(19) United States
(12) Patent Application Publication
(10) Pub. No.: US 2015/0123165 A1
(43) Pub. Date: May 7, 2015

(54) HIGH-VOLTAGE INSULATED GATE TYPE POWER SEMICONDUCTOR DEVICE AND METHOD OF MANUFACTURING THE SAME

(71) Applicant: KYUSHU INSTITUTE OF TECHNOLOGY, Fukuoka (JP)

(72) Inventors: Ichiro Omura, Fukuoka (JP); Masahiro Tanaka, Fukuoka (JP); Masanori Tsukuda, Fukuoka (JP); Yamato Miki, Fukuoka (JP)

(73) Assignee: KYUSHU INSTITUTE OF TECHNOLOGY, Fukuoka (JP)

(21) Appl. No.: 14/404,914

(22) PCT Filed: May 29, 2013
(86) PCT No.: PCT/JP2013/064943

§ 371 Date: Dec. 1, 2014

(30) Foreign Application Priority Data
May 30, 2012 (JP) 2012-123462
Sep. 5, 2012 (JP) 2012-195347

(51) Int. Cl. H01L 29/739; H01L 29/08; H01L 21/265; H01L 29/423; H01L 29/66

(52) U.S. Cl. CPC H01L 29/7397; H01L 29/4236; H01L 29/66348; H01L 21/265; H01L 29/0804
USPC 257/139; 438/138

(57) ABSTRACT

A high-voltage insulated gate type power semiconductor device includes a low-concentration first conductivity type base layer; a plurality of trenches selectively formed with large intervals and narrow intervals provided alternately, in a front surface of the low-concentration first conductivity type base layer; a gate insulating film formed on a surface of each of the plurality of trenches; a gate electrode formed inside the gate insulating film; and a second conductivity type base layer selectively formed between the adjacent trenches sharing the narrow interval. The high-voltage insulated gate type power semiconductor device includes a high-concentration first conductivity type source layer selectively formed on a front surface of the second conductivity type base layer.

### TECHNICAL FIELD

The present invention relates to a power semiconductor device, and more particularly, to a high-voltage insulated gate type power semiconductor device with a reduced conduction loss and a method of manufacturing the same.

### BACKGROUND ART

As for the high-voltage insulated gate type semiconductor device, an IGBT (Insulated Gate Bipolar Transistor) has been widely used. FIG. 1 shows a structure diagram of the IGBT.

As shown in FIG. 1, an IGBT structure includes trenches 2 and 3 selectively formed in a front surface of a low-concentration N type layer (N base layer 1) with large intervals and narrow intervals provided alternately, gate insulating films 4 and 5 formed on surfaces of the trenches 2 and 3, respectively, polysilicon gate electrodes (control electrodes) 6 and 7 formed inside the gate insulating films 4 and 5, respectively, a P base layer (P well layer) 8 selectively formed between the adjacent trenches sharing the narrow interval, a high-concentration N source layer 9 selectively formed on a front surface of the P base layer 8, and a first main electrode (emitter electrode 10) connected to each of the P base layer 8 and the N source layer 9. A MOS transistor structure is formed in surface portions of the N source layer 9, the P base layer 8, and the N base layer 1, and a P type layer (a P type layer 11 having an unfixed potential) is formed between the adjacent trenches sharing the large interval to have the same depth as the trench and so as not to be connected to the emitter electrode 10 or so as to be connected to the emitter electrode 10 through a high resistor. Furthermore, the IGBT structure includes an N buffer layer 12 uniformly formed on a back surface of the N base layer 1 so as to have a higher impurity concentration than the N base layer 1, a high-concentration P type layer (P emitter layer 13) uniformly formed on a front surface of the N buffer layer 12, and a second main electrode (collector electrode 14) uniformly formed on a front surface of the P emitter layer 13.

As for the IGBT having the trench structure, various kinds of proposals and studies have been made as disclosed in Patent Document 1 and Non-patent Documents 1 to 9.

### PRIOR ART DOCUMENTS

### Patent Document

Patent Document 1: U.S. Pat. No. 7,709,887

### Non-Patent Documents

Non-patent Document 1: M. Kitagawa, et al., “A 4500 V injection enhanced insulated gate bipolar transistor (IEGT) operating in a mode similar to a thyristor”, IEDM Technical Digest, pp. 679-682, 1993.

Non-patent Document 2: M. Harada, et al., “600 V Trench IGBT in Comparison with Planar IGBT—An Evaluation of the Limit of IGBT performance-”, Proc. of the 6th International Symposium on Power Semiconductor Devices & IC's (ISPSD), pp. 411-416, 1994.

Non-patent Document 3: M. Momose, et al., “A 600 V Super Low Loss IGBT with Advanced Micro-P Structure for the next Generation IPM”, Proc. of the 22nd International Symposium on Power Semiconductor Devices & IC's (ISPSD), pp. 379-382, 2010.

Non-patent Document 4: T. Laska, et al., “The Field Stop IGBT (FS IGBT)-A New Power Device Concept with a Great Improvement Potential”, Proc. of 12th ISPSD, pp. 355-358, 2000.

Non-patent Document 5: A. Nakagawa, “Theoretical Investigation of Silicon Limit Characteristics of IGBT, Proc. of the 18th International Symposium on Power Semiconductor Devices & IC's (ISPSD), Session 1-2, 2006.

Non-patent Document 6: M. Takei, et al., “DB (Dielectric Barrier) IGBT with Extreme Injection Enhancement”, Proc. of the 22nd International Symposium on Power Semiconductor Devices & IC's (ISPSD), pp. 383-386, 2010.

Non-patent Document 7: M. Baus, et al., “Fabrication of Monolithic Bidirectional Switch (MBS) devices with MOS-controlled emitter structures”, Proc. of the 18th International Symposium on Power Semiconductor Devices & IC's (ISPSD), Session 6-28, 2006.

Non-patent Document 8: Robert H. Dennard, et al., “Design of Ion-Implanted MOSFET's with Very Small Physical Dimensions”, IEEE Journal of Solid-State Circuits, Vol. SC-9, No. 5, pp. 256-268, October 1974.

Non-patent Document 9: M. Tanaka, et al., “Structure Oriented Compact Model for Advanced Trench IGBTs without Fitting Parameters for Extreme Condition: part I”, Microelectronics Reliability 51, pp. 1933-1937, 2011.

### SUMMARY OF THE INVENTION

### Problems to be Solved by the Invention

According to the above-described conventional IGBT structure, depth of the trench gate structure and the impurity diffusion layer (P type layer 11 having the unfixed potential) are about 5 μm which is larger than that of a normal LSI process. Therefore, there are problems that it takes time in the process of forming the structure, such as an RIE (Reactive Ion Etching) process in forming the trench gate, and a heat diffusion process in forming the diffusion layer. In addition, as described above, when the trench structure is formed deeply in the wafer, the warpage is generated in the wafer, so that it is difficult to increase a diameter of the wafer which is indispensable to improve mass productivity. Furthermore, according to a recent IGBT, its wafer thickness is reduced to about 100 μm to improve the performance, and it is further likely to be reduced. However, it is difficult to further reduce the thickness of the structure having the trench gate and the diffusion layer deeply formed in the wafer.

Here, an example of a process of manufacturing the conventional IGBT will be described with reference to FIG. 10.

(a) As shown in FIGS. 10 (a-1) and (a-2), as the front surface structure of the IGBT, the P type layer 11 having the unfixed potential, the P base layer 8, the N source layer 9, the gate insulating films 4 and 5, and the emitter electrode 10 are formed in a semiconductor substrate 20 serving as the N base layer 1 having a thickness of 400 μm to 600 μm. The P type layer 11 is made of boron, and the N source layer 9 is made of phosphor and arsenic. The gate insulating films 4 and 5 are made of thermally-oxidized film, CVD oxide film, polyimide, or the like. The emitter electrode 10 is made of AlSi or Ti—Al.

(b) As shown in FIGS. 10 (b-1) and (b-2), the semiconductor substrate 20 is turned upside down, a protection tape 30 is attached on a back surface, and the semiconductor substrate 20 is thinned to 100 μm to 150 μm by grinding with a grinder and wet etching.

(c) As shown in FIGS. 10 (c-1) and (c-2), as the back surface structure of the IGBT, the N buffer layer 12 and the P emitter layer 13 are formed by impurity ion implantation processes and then short-time (several 10 sec. to several sec.) annealing processes. The N buffer layer 12 is made of phosphor, and the P emitter layer 13 is made of boron. Since only the back surface is heated at high temperature (about 1000° C.) by annealing, the IGBT structure on the front surface is not affected. Then, the collector electrode 14 (made of Ai-Ni—Au, for example) is attached.

(d) As shown in FIGS. 10 (d-1) and (d-2), the protection tape 30 is removed. Then, sintering is performed at about 400° C.

Thus, the above is the conventional process of manufacturing the high-performance IGBT having the deep diffusion layer, but this has the following problems.

Problems when the Back Surface and the Front Surface are Formed in this Order

(i) A degree of freedom of the back surface process is reduced, so that the performance of the IGBT cannot be improved, that is, the loss cannot be reduced. In addition, when the lifetime is controlled with respect to the highly-implanted carriers, the number of the processes is increased, and in addition, a high-temperature operation becomes difficult to perform.

Problems when the Front Surface and the Back Surface are Formed in this Order

(ii) The number of processes is increased, and in addition, a yield is lowered due to a scratch, crack, contamination because the fine front surface structure is to be in contact with a stage, loader, or protection tape.

(iii) The semiconductor substrate 20 could be damaged in the grinding with a grinder during the process.

(iv) Flatness of the back surface is damaged, so that in-plane characteristics vary. In addition, the back surface process cannot be deeply formed, so that a waveform is largely oscillated.

(v) The back surface is difficult to pattern because of unevenness caused when the protection tape is attached.

Thus, it is an object of the present invention to provide a high-voltage insulated gate type power semiconductor device (IGBT) which needs only a short time to form a trench gate in a wafer, can make a suitable response to a thinned and large-diameter wafer, and improve mass productivity, and a method of manufacturing the same.

### Solutions to the Problems

A high-voltage insulated gate type power semiconductor device according to the present invention includes:

a low-concentration first conductivity type base layer;

a plurality of trenches selectively formed with large intervals and narrow intervals provided alternately, in a front surface of the low-concentration first conductivity type base layer;

a gate insulating film formed on a surface of each of the plurality of trenches;

a gate electrode formed inside the gate insulating film;

a second conductivity type base layer selectively formed between the adjacent trenches sharing the narrow interval;

a high-concentration first conductivity type source layer selectively formed on a front surface of the second conductivity type base layer;

a first main electrode connected to each of the second conductivity type base layer and the first conductivity type source layer;

a MOS transistor structure formed in surface portions of the first conductivity type source layer, the second conductivity type base layer, and the low-concentration first conductivity type base layer;

a second conductivity type layer formed between the adjacent trenches sharing the large interval so as not to be connected to the first main electrode, or connected to the first main electrode through a high resistor, the second conductivity type layer having the same degree of depth as the trench, and having an unfixed potential;

a first conductivity type buffer layer uniformly formed on a back surface of the low-concentration first conductivity type base layer so as to have a higher impurity concentration than the low-concentration first conductivity type base layer;

a high-concentration second conductivity type emitter layer uniformly formed on a front surface of the first conductivity type buffer layer; and

a second main electrode formed on a front surface of the second conductivity type emitter layer, wherein

a width S, trench depth D_{T}, gate insulating film thickness T_{OX}, and a gate drive voltage V_{ge} of a mesa region that is a structural portion including portion having the gate insulating film formed on the surface of the trenches and the MOS transistor structure, have an inverse relationship with a scaling ratio k to reduce a size of a reference structure, and a cell width 2W is the same as a cell width in the reference structure.

Here, the reference structure depends on manufacturers, and for example, the trench depth D_{T} is 5 μm to 6 μm, a distance between centers of the adjacent trenches is 3 μm to 4 μm, the total cell width 2W is 15 μm to 20 μm, and the gate drive voltage V_{ge} of the power semiconductor device having the reference structure in an on state is 15 V. A certain manufacturer employs a square structure as the trench structure instead of the stripe structure, so that the above values may be taken as an area ratio. That is, an area ratio of an area which is in contact with the emitter electrode to an area which is not in contact with the emitter electrode or in contact through the high resistor, in an area sandwiched between the centers of the trenches is 1:4 to 1:6. When the present invention is applied to the above basic structure, the scaling ratio k is to be equal to or greater than 3, and preferably equal to or greater than 5.

In the case where the above scaling ratio k is applied, it is preferable that the trench depth D_{T} is 3 μm or less, an average value of the mesa width 2S serving as a silicon portion sandwiched between the two adjacent trenches is 2 μm or less, the gate oxide film thickness Tₒₓ is 333 nm or less, the gate drive voltage V_{ge} is about 5 V, and the cell width 2W is about 16 μm. This is because the effect can be most remarkably achieved until k=3, due to current voltage characteristics in FIG. 5(a) which will be described below.

According to one aspect of the present invention, a value provided by dividing an average value of impurity concentration gradients of the second conductivity type emitter layer by a total impurity amount of the second conductivity type emitter layer is smaller than values provided by dividing average values of the impurity concentration gradients of the second conductivity type layer having the unfixed potential and the second conductivity type base layer by total impurity amounts of the second conductivity type layer and the second conductivity type base layer, respectively. The impurity concentration gradient corresponds to a heat history of the impurity diffusion. According to a manufacturing method in the present invention, the semiconductor structure on the back surface side is manufactured first, and then the IGBT structure on the front surface side is manufactured, so that the value of the impurity concentration gradient of the semiconductor device on the back surface side structure is smaller than that of the front surface side structure.

According to another aspect of the present invention, a thickness of the second conductivity type emitter layer formed on the back surface of the low-concentration first conductivity type base layer is between 1 μm and 10 nm. The above thin first conductivity type buffer layer and second conductivity type emitter layer can be manufactured by the short-time annealing.

According to a method of manufacturing the high-voltage insulated gate type power semiconductor device in the present invention, the first conductivity type buffer layer and the second conductivity type emitter layer are formed on the back surface of the low-concentration first conductivity type base layer, and subsequently, the front surface structure including the trench and the MOS transistor structure is formed on the front surface of the low-concentration first conductivity type base layer. According to this manufacturing process, the high-performance (low-loss) IGBT can be manufactured with the less steps and high yield.

### Effects of the Invention

According to the present invention, it is possible to provide the high-voltage insulated gate type power semiconductor device which needs only a short time to form the trench gate in the wafer, can make a suitable response to the thinned and large-diameter wafer, and improve mass productivity.

Furthermore, according to the manufacturing method of the present invention, the high-performance (low-loss) IGBT can be manufactured with the less steps and high yield.

### BRIEF DESCRIPTION OF THE DRAWINGS

FIG. 1 is a structure diagram of a trench gate type IGBT.

FIG. 2 is a structure diagram showing current flows in the trench gate type IGBT.

FIG. 3 is a structure diagram showing a comparison between miniaturization of only a major part according to the present invention and simple miniaturization according to a conventional method, in which (a) shows a basic form, (b) and (c) are the case of the major part miniaturization according to the present invention, and (b′) and (c′) are the case of the simple miniaturization according to the conventional method.

FIG. 4 is a graph showing Jc-Vce characteristics obtained by changing the scale ratio k of the miniaturization.

FIG. 5 are graphs each showing a change in collector current with respect to a collector-emitter voltage when a current flows, in which (a) is the case of the major part miniaturization according to the present invention, and (b) is the case of the simple miniaturization according to the conventional method.

FIG. 6 are graphs each showing an stored carrier (hole) distribution in an N base layer, in which (a) is the case of the major part miniaturization according to the present invention, and (b) is the case of the simple miniaturization according to the conventional method.

FIG. 7 are manufacturing process diagrams each showing a manufacturing method according to a first embodiment of the present invention, in which (a-1) and (b-1) are front perspective views, and (a-2) and (b-2) are enlarged cross-sectional views.

FIG. 8 are manufacturing process diagrams each showing a manufacturing method according to a second embodiment of the present invention, in which (a-1) to (d-1) are front perspective views, and (a-2) to (d-2) are enlarged cross-sectional views.

FIG. 9 is a graph showing characteristics of a potential of a gate electrode and collector current with respect to changes of the scaling ratio k when P type polysilicon is used.

FIG. 10 are manufacturing process diagrams each showing a conventional method of manufacturing an IGBT, in which (a-1) to (d-1) are front perspective views, and (a-2) to (d-2) are enlarged cross-sectional views.

### EMBODIMENTS OF THE INVENTION

Hereinafter, embodiments of the present invention will be specifically described. Here, it is to be noted that the description will be given assuming that a first conductivity type is an N type and a second conductivity type is a P type in this embodiment, but they may be exchanged such that the first conductivity type is the P type and the second conductivity type is the N type.

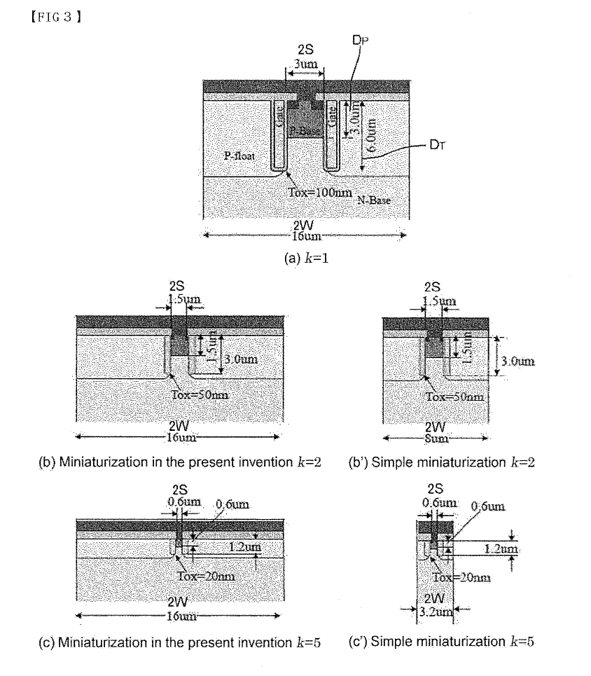

As shown in FIG. 2, implantation efficiency on a cathode side is modeled with structural parameters of a trench gate type IGBT. According to this model, an electron current from a gate of a MOS (Metal Oxide Semiconductor) is divided into two paths in the mesa region between the P base layer 8 and the N base layer 1. That is, those are currents having current densities shown by Jₙ^{mesa} and Jₚ^{mesa}.

Jₙ^{mesa} and Jₚ^{mesa} are modeled as follows. Here, it is assumed that electrons and holes are diffused in one dimensional manner. Due to the occurrence of conductive modulation by conductivity modulation, the densities of the electrons and the holes are maintained almost the same. As a result, the following differential equation can be obtained as an ambipolar diffusion formula.

$$\begin{matrix}[ Formula 1 ] & \\ {μ}_{p} \cdot {J}_{n}^{mesa} - {μ}_{n} \cdot {J}_{p}^{mesa} = 2 \cdot {μ}_{p} \cdot {μ}_{n} \cdot kT \frac{d n}{d x} & ( 1 )\end{matrix}$$

Here, μₚ and μₙ represent a hole mobility and an electron mobility, respectively, k represents the Boltzmann constant, T represents an absolute temperature, and dn/dx represents a density gradient of the electrons and holes.

Furthermore, an electron current formula in an electron stored layer (formed in an insulating film surface of a trench gate sidewall which is in contact with the N base layer 1) is expressed by the following formula.

$$\begin{matrix}[ Formula 2 ] & \\ {I}_{n}^{acc} = - {μ}_{acc} \cdot {Q}_{acc} \frac{d {φ}_{n}}{d x} & ( 2 )\end{matrix}$$

Here, μ_{acc} represents an electron mobility in the electron stored layer formed on a trench gate side surface when a gate voltage is applied, Q_{acc} represents a charge density of the electron stored layer per unit area, and dφₙ/dx represents a gradient of an electron potential (electron quasi-Fermi potential) along the electron stored layer.

Equations of a cell current and a mesa current are obtained based on a cell width and a mesa width shown in FIG. 2.

[Formula 3]

W·Jₚ^{cell}=S·Jₚ^{mesa} (3)

[Formula 4]

W·Jₙ^{cell}=Iₙ^{acc}+S·Jₙ^{mesa} (4)

Here, W represents a half pitch of the cell width, and S represents a half width of the P base layer (mesa width).

A formula (5) is obtained according to the formulas (1) to (4).

$$\begin{matrix}[ Formula 5 ] & \\ ( \frac{{μ}_{p}}{{μ}_{n}} {( \frac{{μ}_{acc} \cdot {Q}_{acc}}{q \cdot {μ}_{n} \cdot n ( x ) \cdot S} + 1 )}^{- 1} + 1 ) {γ}_{n} - 1 = \frac{2 q \cdot {D}_{p}}{J} \frac{S}{W} \frac{d n}{d x} & ( 5 )\end{matrix}$$

Here, q represents an elementary charge, γₙ represents an electron implantation efficiency, and Dₚ represents a depth of the P type layer 11.

The formula (5) is a basic formula of a scaling law.

The scaling law in the present invention is collectively shown in Table 1. This scaling law can be logically derived from the formula (5). The formula (5) shows that a scaled device has the same implantation efficiency under the following conditions.

$$\begin{matrix}[ Formula 6 ] & \\ \frac{{μ}_{acc} \cdot {Q}_{acc}}{q \cdot {μ}_{n} \cdot n ( x ) \cdot S} = const . & ( 6 ) \\ [ Formula 7 ] & \\ \frac{S}{W} \frac{d n}{d x} = const . & ( 7 )\end{matrix}$$

Even when an electric field intensity of the gate oxide film is scaled down so as to satisfy Eₒₓ′=Eₒₓ/k and an electric field intensity in the gate oxide film is reduced, the formula (6) is constant with respect to a certain constant value of n (x), and as a result, the formula (7) can be derived from the formula (5) as long as the density of the current flowing in the IGBT is the same. More specifically, as described above, even under the condition that the electric field intensity of the gate oxide film is scaled down so as to satisfy Eₒₓ′=Eₒₓ/k and the electric field intensity in the gate oxide film is reduced, as long as the half pitch W of the cell width is constant, dn/dx in the mesa portion is increased inversely as the half width S of the P base layer is reduced, so that even when a depth (D_{T}−D_{P}) of the trench which projects from the P base layer 8 is reduced in proportional to the half width S, the carrier density under the trench is not changed. In addition, under this condition, the gate voltage is reduced inversely with the square of k, that is, V_{g}′=V_{g}/k².

The above conclusion shows that the density of the carriers (the electrons and the holes) to pass the current is not changed under the condition that the major part of the IGBT (the MOS channel region sandwiched between the two trenches) is reduced, the gate voltage is reduced inversely with the square of the k, and the electric field of the gate insulating film is reduced inversely with k. In general, as for the gate insulating film, even when it is thinned, its breakdown electric field does not change or it is increased, so that the condition could be Eₒₓ′=Eₒₓ and based on this condition, the left-hand side of the formula (6) is not constant, but increased as the size is reduced.

When this result is applied to the formula (5), the members acting on γₙ (members in parentheses) is reduced, and under the condition that γₙ is the same, an absolute value of the left-hand side of the formula is increased. As a result, the left-hand side of the formula (7) in the mesa portion, that is, S/W*dn/dx is not constant as described above, but it is increased. This means that compared with the above-described case, the dn/dx in the mesa portion is larger and the carrier density can be more increased. In this case, since Eₒₓ′=Eₒₓ is satisfied, the scaling of the voltage V_{g} applied between the gate and emitter is such that V_{g}′=V_{g}/k. That is, without applying a high electric field to the gate oxide film, a high carrier amount can be achieved due to the miniaturization, and a conduction loss of the IGBT can be reduced. That is, the lower V_{ce} (sat) can be achieved.

TABLE 1

| | Scaling ratio | |
|---|---|---|
| | Electric field | Electric field |
| | intensity in | intensity in |
| | gate oxide film | gate oxide film |
| Parameters | Eₒₓ’ = Eox/k | Eₒₓ = Constant |
| Gate voltage Vg | 1/k² | 1/k |
| P base layer half width S | 1/k | |
| Cell half pitch W | 1 | |
| N emitter width W_{E} | 1/k | |
| Trench depth D_{T} | 1/k | |
| P base layer depth D_{P} | 1/k | |
| N emitter depth D_{E} | 1/k | |
| Contact hole half width W_{C} | 1/k | |
| Gate insulating film thickness Tₒₓ | 1/k | |
| Gate-emitter capacity C_{ge} | 1 | |
| Gate-collector capacity C_{gc} | 1 | |
| Collector-emitter capacity C_{ce} | 1/k | |
| Contact hole current density J_{ch} | k | |
| Gate charge Q_{g} | 1/k² | 1/k |
| Electron implantation efficiency γₙ | 1 | >1 |
| Stored carrier density n = p | 1 | >1 |

The above-described scaling law was proved and performance improvement was verified by two-dimensional TCAD simulation. They were made on the assumption that the IGBT structure is a thin wafer type punch-through structure at a level of 1.2 kV.

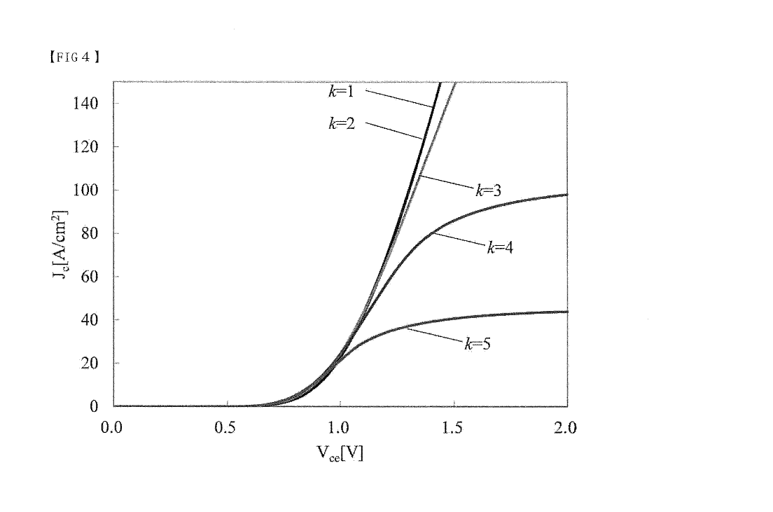

FIG. 3 show a comparison between the miniaturization of only the main portion according to the present invention, and simple miniaturization according to the conventional method. In FIG. 3, (a) shows a basic form, (b) and (c) show the case of the miniaturization of the main portion according to the present invention, and (b′) and (c′) show the case of the simple miniaturization according to the conventional method. The scaling ratio k is 2 in (b) and (b′), and the scaling ratio k is 5 in (c) and (c′), but Table 2 shows data of the scaled devices in the cases where k=2, 3, and 4 in addition to the above.

TABLE 2

| Scaling ratio k | k = 1 | k = 2 | k = 3 | k = 4 | k = 5 |
|---|---|---|---|---|---|
| Cell width (the present invention): | 16.0 | 16.0 | 16.0 | 16.0 | 16.0 |
| 2W [μm] | | | | | |
| Cell width (simple miniatur- | (16.0) | (8.0) | (5.3) | (4.0) | (3.2) |
| ization): 2W [μm] | | | | | |
| Mesa width: 2S [μm] (1/k) | 3.0 | 1.5 | 1.0 | 0.8 | 0.6 |
| Trench depth: D_{T} [μm] (1/k) | 6.0 | 3.0 | 2.0 | 1.5 | 1.2 |
| Gate insulating film thickness: Tₒₓ | 100 | 50 | 33.3 | 25 | 20 |
| [nm] (1/k) | | | | | |
| Gate voltage: V_{ge} [V] (1/k) | 15.0 | 7.5 | 5.0 | 3.75 | 3.0 |

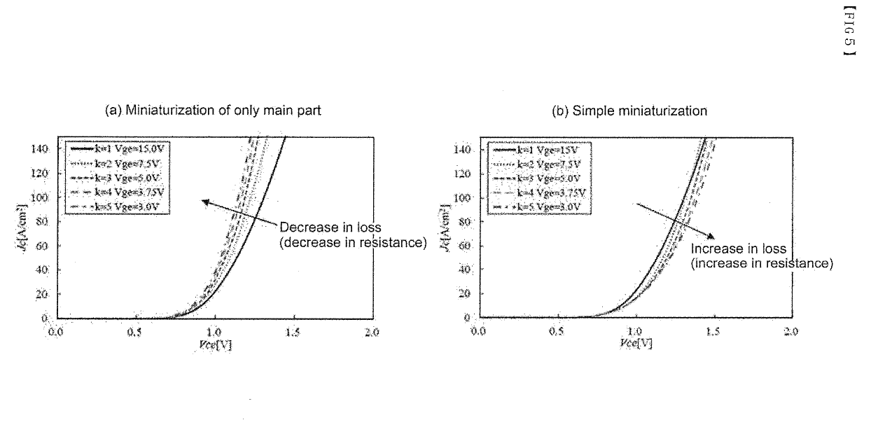

FIG. 4 shows J_{c}−V_{ce} characteristics when the gate electric field is such that Eₒₓ′=Eₒₓ/k in the scaled devices in k=1 to 5.

In the cases where k=1 and k=2, they coincide with each other, but in the case where k=3 to 5, their saturation currents become small. This is because the gate threshold voltage Vₜₕ shown in the following formula is moved due to the scaling.

$$\begin{matrix}[ Formula 8 ] & \\ {V}_{th} = \frac{\sqrt{2 {ɛ}_{0} {ɛ}_{Si} q {N}_{A} {φ}_{S}}}{{C}_{ox}} + {φ}_{S} & ( 8 )\end{matrix}$$

Here, ∈₀ represents permittivity of vacuum, ∈ₛᵢ represents relative permittivity of silicon, Cₒₓ represents capacity of the gate in the MOS structure per unit area, N_{A} represents a concentration of an acceptor (P type impurity such as boron) in the P base layer (corresponding to a P well in the MOS structure, in general), and φₛ represents a surface potential.

The gate capacity per unit area is increased such that Cₒₓ′=kCₒₓ due to the scale-down, so that the Vₜₕ is reduced. However, Vₜₕ is not correctly scaled even when N_{A} and φₛ are constant.

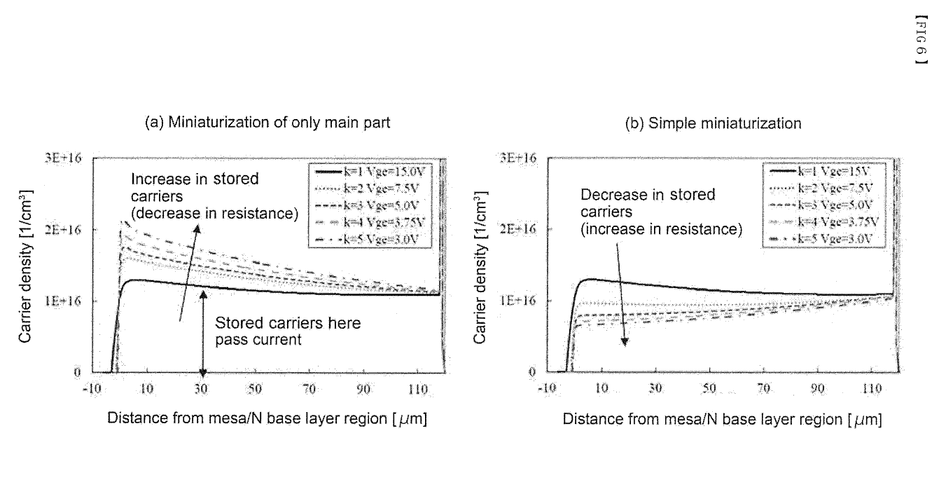

FIG. 5 shows a comparison of J_{c}−V_{ce} characteristics in a case where the gate oxide film electric field is constant between (a) the miniaturization of only the main portion according to the present invention and (b) the simple miniaturization according to the conventional method. As shown in (a), V_{ce} (sat) is reduced due to the scale-down. Meanwhile, as shown in the case (b), V_{ce} (sat) is increased due to the scale-down, and the loss is increased.

FIG. 6 shows a comparison of a carrier distribution in the N-Base in the on state between (a) the miniaturization of only the main portion according to the present invention and (b) the simple miniaturization according to the conventional method. As shown in (a), the carrier density on the cathode side is increased due to the scale-down. That is, the high γₙ and the low V_{ce} (sat) can be obtained in the shallow trench by the scale-down. Meanwhile, as shown in the case of (b), the stored carrier density is reduced in the shallow trench by the scale-down.

As described above, according to the present invention, it has been proved that the carrier stage can be increased in the structure of the shallow trench gate and the shallow doping, by the scaling law of the trench gate IGBT.

When the trench IGBT is scaled down by reducing the trench depth, the heat history, the doping depth, and the oxide film thickness, device performance can be improved and the wafer having the large diameter (large-diameter wafer) can be used. A collector voltage drop can be very small with a scaling factor by which the gate oxide film electric field intensity is not increased. Therefore, the scaling law according to the present invention increases a possibility that the mass production can be implemented with the CMOS process. Especially, when the scaling ratio is 5 or less, and the trench depth is reduced to about 1 μM and the thickness of the gate insulating film is reduced to about 20 nm, a thermal process is hardly needed in the manufacturing process, which does not cause a defect in wafer and a reduction in carrier lifetime, so that the IGBT can be further low in conduction loss. In addition, since the warpage of wafer is not generated, the IGBT can be manufactured with the large-diameter wafer, so that the productivity can be considerably improved.

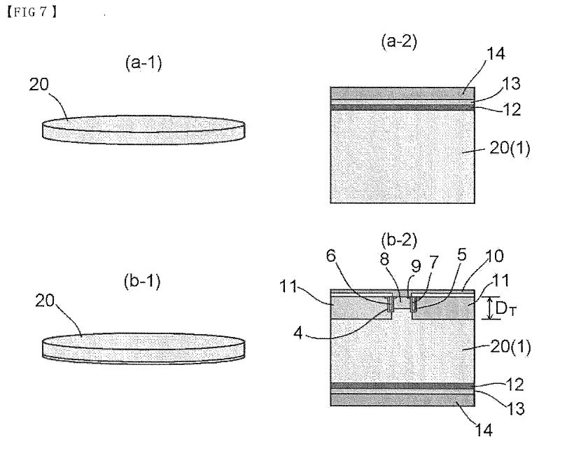

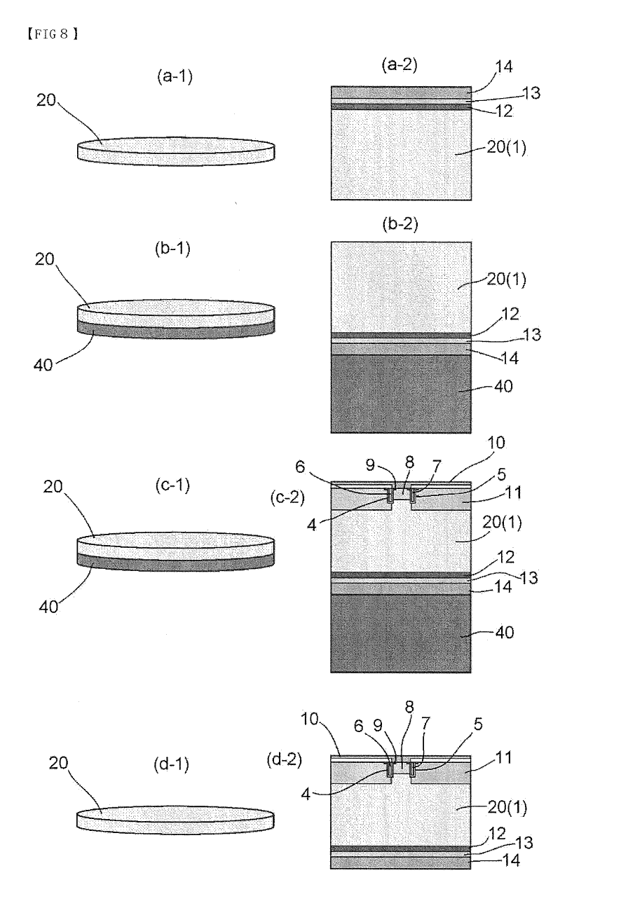

Next, a description will be given to a method of manufacturing the IGBT in the first embodiment of the present invention, with reference to FIG. 7.

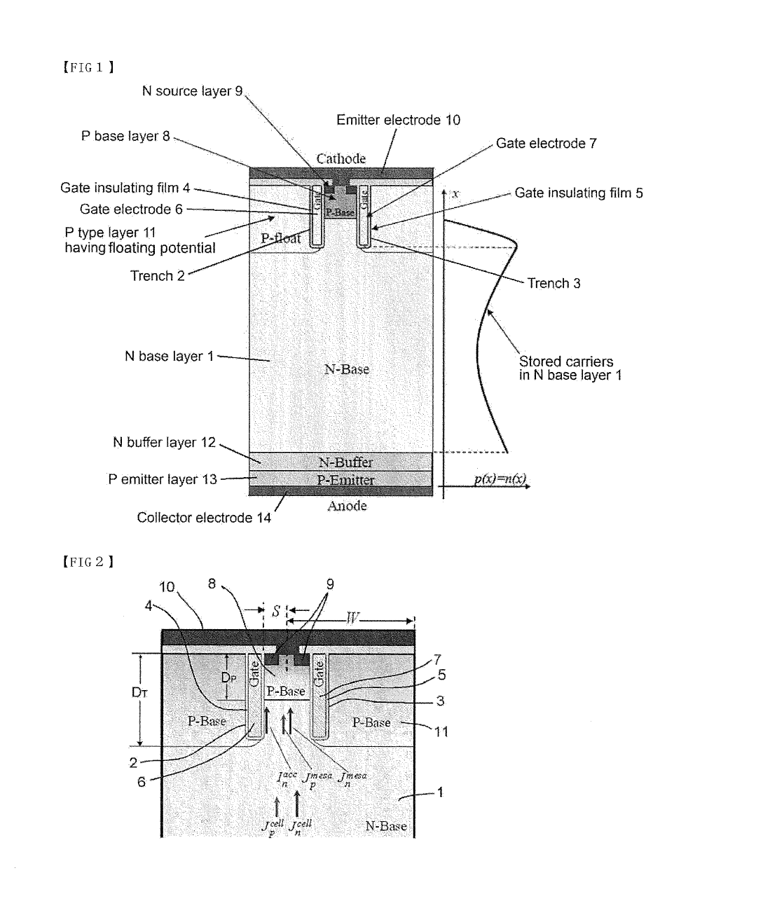

(a) As shown in FIGS. 7 (a-1) and (a-2), as a back surface structure of a semiconductor substrate 20 having a thickness of 100 μm to 150 μm, the N buffer layer 12 and the P emitter layer 13 are formed by a short-time (several 10 msec. to several sec.) annealing. Then, the collector electrode 14 as a back surface electrode is attached thereon. Here, a thickness of the P emitter layer 13 is 1 μm or less which can be formed by the short-time annealing.

This IGBT back surface structure has been already practically used as the thin wafer IGBT and a field stop IGBT (FS-IGBT).

The method in the present invention has the following benefits compared with the conventional method.

Conventionally, deterioration in switching characteristics due to many carriers in the N base has been improved by a method in which the wafer is irradiated with high-energy electrons, protons or helium or the like to reduce the carrier lifetime in the wafer, so as to accelerate recombination between the electrons and the holes in the N base, and reduce the internal carriers. However, the above irradiation process is high in cost, and in addition, a semiconductor crystal defect is unnecessarily generated, which causes a deterioration in characteristics and a decrease in reliability. Especially, the irradiation with protons or the irradiation with helium has a great effect on a local reduction in the carrier lifetime, but the problems are that a leak current is increased at high temperature, reliability deteriorates, and process cost is increased due to the irradiation and annealing. The above back surface structure has a benefit that the device can be manufactured with a high-quality crystal because there is no need to reduce the carrier lifetime. Meanwhile, the formation of the back surface structure has the problem in the manufacturing process. That is, there is an effect of preventing holes from being implanted from the P emitter by forming the extremely thin diffusion layer on the back surface, but there is a need to perform a very low thermal process (at low temperature for a short time) to form the diffusion layer, so that this process needs to be performed after a formation of a front surface structure (a diffusion layer of 5 μm to 6 μm) in a high thermal process (at high temperature for a long time). Therefore, this means that the wafer is inserted in a manufacturing device with its upper surface which has been formed once, facing downward, so that various low yield problems are caused by a surface damage or the like.

(b) As shown in FIGS. 7 (b-1) and (b-2), as the diffusion layers in the front surface structure, the gate insulating films 4 and 5, the gate electrodes 6 and 7 are formed. As the diffusion layers, the P type layer 11 having the unfixed potential is made of boron, and the N source layer 9 is made of phosphor and arsenic. The gate insulating films 4 and 5 are made of thermally-oxidized film, CVD oxide film, polyimide, or the like. The gate electrodes 6 and 7 are made of AlSi or Ti—Al. The diffusion layer is formed by high-acceleration ion implantation (several 100 keV) and short-time annealing (about 1000° C.). A CVD film is preferably used as the oxide film to avoid the high temperature and long period of time. To form the emitter electrode 10, sintering at about 400° C. is performed as well. Here, the thickness of the P type layer 11 having the unfixed potential is set to 1.5 μm or less since a depth provided by the ion implantation is about 1 μm in general. A conventional depth has been greater, but this depth can be realized by the high-acceleration ion implantation.

According to this embodiment, the process for the front surface does not affect the back surface structure because the heat history in the front surface process is lower than that in the back surface, or the front surface is also subjected to the short-time annealing so that thermal transmission to the back surface is limited. That is, the front surface structure is about 1 μm or less, and the very low heat history can be provided by the high-acceleration ion implantation or the selective ion implantation to the portion of the shallow trench and then the short-time annealing. As a result, the back surface structure is manufactured first, and then the front surface structure is manufactured, so that the process can be performed with a high manufacturing efficiency.

In this manufacturing process, there is a case where the back surface electrode (collector electrode 14) is formed at the end in order to avoid a metal spike and contamination. Furthermore, there is a case where the front surface is protected by a tape when the back surface structure is formed.

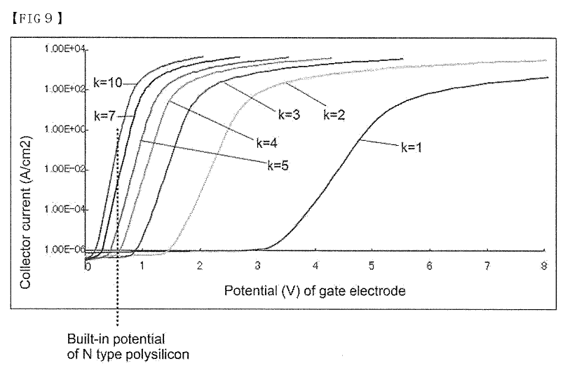

Next, a description will be given to a method of manufacturing an IGBT in the second embodiment of the present invention, with reference to FIG. 8.

(a) As shown in FIGS. 8 (a-1) and (a-2), as a back surface structure of the semiconductor substrate 20 having the thickness of 100 μm to 150 μm, the N buffer layer 12 and the P emitter layer 13 are formed by short-time (several 10 msec. to several sec.) annealing. Then, the collector electrode 14 is formed as the back surface electrode. Here, the thickness of the P emitter layer 13 is 1 μm or less which can be formed by the short-time annealing.

(b) As shown in FIGS. 8 (b-1) and (b-2), a stage substrate 40 is attached. The stage substrate 40 may be made of a quartz wafer, silicon wafer, ceramic, polysilicon, or the like. As a bonding material, an oxide film or resin may be used.

(c) As shown in FIGS. 8 (c-1) and (c-2), as the diffusion layers in the front surface structure, the gate insulating films 4 and 5, and the gate electrodes 6 and 7 are made. As the diffusion layers, the P type layer 11 having the unfixed potential is made of boron, and the N source layer 9 is made of phosphor and arsenic. In addition, when the P type layer 11 is formed, a withstand voltage in a blocked state (in an off state) can be improved. The gate insulating films 4 and 5 are made of thermally-oxidized film, CVD oxide film, polyimide, or the like. The gate electrodes 6 and 7 are made of AlSi or Ti—Al. The diffusion layer is formed by high-acceleration ion implantation (several 100 keV) and short-time annealing (about 1000° C.). A CVD film is preferably used as the oxide film in order to avoid the high temperature and long period of time. To form the emitter electrode 10, sintering at about 400° C. is performed as well.

(d) As shown in FIGS. 8 (d-1) and (d-2), the stage substrate 40 is removed.

According to the manufacturing method in this second embodiment, the stage substrate 40 is attached during the processes in order to solve the problem that in the case where the wafer (semiconductor substrate 20) is very thin, or the wafer has the large diameter, the wafer is broken or a position cannot be focused in a process such as photolithography because of warpage of the wafer, so that although the number of the steps is increased, the yield is improved compared with the first embodiment.

In addition, in this manufacturing process, there is a case where the back surface electrode (collector electrode 14) is attached at the end in order to avoid the metal spike and contamination.

The manufacturing process of the IGBT in each embodiment described above is only one example, and even when a thick semiconductor substrate is used and a final thickness of the N base layer is 500 μm, and even when the final thickness of the N base layer is thinned to 40 μM to 100 μM by the method described in the first or second embodiment, the performance can be enhanced and the mass production can be achieved.

In each of the first embodiment and the second embodiment, polysilicon is used for the material for the gate electrodes 6 and 7 provided in the trenches 2 and 3, respectively, but when the scaling ratio k is 5 or more especially, P type polysilicon is preferably used. According to the conventional IGBT, N type polysilicon is used in order to reduce resistance of the electrode material.

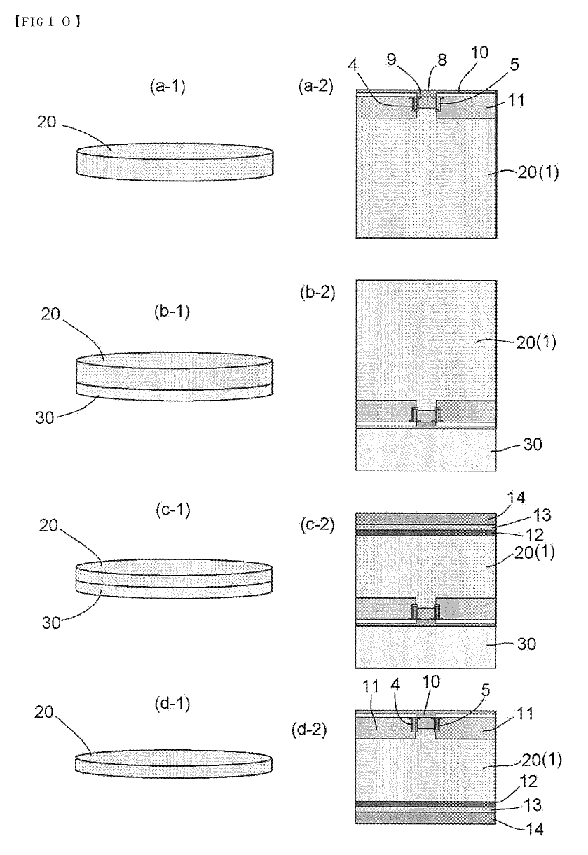

The N type polysilicon is low in resistance compared with the P type polysilicon, so that it is generally used for the gate electrode of the IGBT. As shown in FIG. 9, the N type polysilicon has a positive built-in voltage and the voltage is about 0.5 V to 0.6 V, in general.

However, when the scale ratio k is increased, and the thickness of the gate insulating film is 20 nm or less, a positive voltage corresponding to the built-in voltage is generated in the gate electrode inside the element due to the built-in voltage even when 0 V is applied to the gate terminal, so that this voltage induces some electrons to a P base interface. As shown in FIG. 9, as for the voltage shown by a broken line (built-in voltage of the N type polysilicon), in the case where the scaling ratio k is 5 or more, a collector current (leak current) is increased in the off state at the gate voltage of 0 V together with the increase in the scaling ratio k. As a result, when the N type polysilicon is used for the gate electrode, the off state cannot be maintained due to the leak current unless the gate drive circuit applies a negative voltage to the gate terminal. This becomes problematic when the temperature is high especially.

Meanwhile, according to the embodiment of the present invention, since the P type polysilicon is used, the resistance of the electrode material is increased to some extent, but as the scaling ratio k is increased, the gate charge (gate current) is reduced, so that the increase in the resistance of the electrode material does not matter. Furthermore, when the P type polysilicon is used, due to the negative built-in voltage, it becomes possible to reduce the leak current through the channel of the MOS structure (very small current due to electrons going through the N emitter, the P base surface, and N base). Especially, it becomes possible to reduce the leak current when the voltage V_{GE} between the gate and the emitter is 0 V. As a result, a negative bias is not needed in driving the gate, so that the gate drive circuit can be simple. When the negative bias is not needed when the gate voltage is 5 V or less (or the scaling ratio k is 3 or more), the IC composed of the CMOS can be used for the gate drive circuit, so that the gate drive IC can be provided at low cost.

Furthermore, when each of the gate insulating films 4 and 5 is a high-permittivity gate insulating film made of an oxide of hafnium (Hf), zirconium (Zr), aluminum (Al), or a titanium, or a silicate compound of those, the leak current due to a tunneling current through the gate insulating film can be considerably reduced especially in a case where the scaling ratio k is 10 or more.

As described above, according to the embodiments of the present invention, it is possible to provide the high-voltage insulated gate type power semiconductor device which needs only a short time to form the trench gate in the wafer, can make a suitable response to the thinned and large-diameter wafer, and improve mass productivity.

Furthermore, according to the manufacturing method of the present invention, the high-performance (low-loss) IGBT can be manufactured with the less steps and the high yield.

According to each of the first and second embodiments of the present invention, since the surface of the IGBT is thinned, it is possible to perform the process of the fine LSI at the same time as the process of the IGBT, and it is also possible to provide the control circuit of the IGBT on the same chip.

The present invention can be applied not only to the vertical type IGBT but also to a horizontal type IGBT used in a power IC.

### INDUSTRIAL APPLICABILITY

The present invention can be preferably used for technology of manufacturing the IGBT and other semiconductors, as a future miniaturization technology capable of responding to the large-diameter and thinned wafer.

### EXPLANATION OF THE REFERENCE SIGNS

1: N base layer (low-concentration N type layer)
2, 3: Trench
4, 5: Gate insulating film
6, 7: Gate electrode (control electrode)
8: P base layer (P well layer)
9: N source layer
10: Emitter electrode (first main electrode)
11: P type layer having unfixed potential
12: N buffer layer
13: P emitter layer
14: Collector electrode (second main electrode)
20: Semiconductor substrate
30: Protection tape
40: Stage substrate

1. A high-voltage insulated gate type power semiconductor device comprising:
a low-concentration first conductivity type base layer;
a plurality of trenches selectively formed with large intervals and narrow intervals provided alternately, in a front surface of the low-concentration first conductivity type base layer;
a gate insulating film formed on a surface of each of the plurality of trenches;
a gate electrode formed inside the gate insulating film;
a second conductivity type base layer selectively formed between the adjacent trenches sharing the narrow interval;
a high-concentration first conductivity type source layer selectively formed on a front surface of the second conductivity type base layer;
a first main electrode connected to each of the second conductivity type base layer and the first conductivity type source layer;
a MOS transistor structure formed in surface portions of the first conductivity type source layer, the second conductivity type base layer, and the low-concentration first conductivity type base layer;
a first conductivity type buffer layer formed on a back surface of the low-concentration first conductivity type base layer so as to have a higher impurity concentration than the low-concentration first conductivity type base layer;
a high-concentration second conductivity type emitter layer formed on a front surface of the first conductivity type buffer layer; and
a second main electrode formed on a front surface of the second conductivity type emitter layer, wherein
a width S, trench depth D_{T} of a mesa region that is a structural portion including portion having the gate insulating film formed on the surface of the trenches and the MOS transistor structure, have an inverse relationship with a scaling ratio k to reduce a size of a reference structure, and
a cell width 2W is larger than a length having an inverse relationship with the scale ratio k to reduce the size of the reference structure, and when in the reference structure, the trench depth D_{T} is 5 μm to 6 μm.

2. The high-voltage insulated gate type power semiconductor device according to claim 1, wherein
a width S, trench depth D_{T}, gate insulating film thickness T_{OX}, and a gate drive voltage V_{ge} of a mesa region that is a structural portion including portion having the gate insulating film formed on the surface of the trenches and the MOS transistor structure have an inverse relationship with a scaling ratio k to reduce a size of a reference structure, and
the cell width 2W is larger than the length having the inverse relationship with the scaling ratio k to reduce the size of the reference structure, and the same as or smaller than a reference width, and when in the reference structure, the trench depth D_{T} is 5 μm to 6 μm.

3. The high-voltage insulated gate type power semiconductor device according to claim 1, wherein
the scaling ratio k is equal to or greater than 3, and a value provided by dividing an average value of impurity concentration gradients of the second conductivity type emitter layer by a total impurity amount of the second conductivity type emitter layer is smaller than values provided by dividing average values of the impurity concentration gradients of the second conductivity type layer having the unfixed potential and the second conductivity type base layer by total impurity amounts of the second conductivity type layer and the second conductivity type base layer, respectively.

4. The high-voltage insulated gate type power semiconductor device according to claim 1, wherein
the scaling ratio k is equal to or greater than 5.

5. The high-voltage insulated gate type power semiconductor device according to claim 1, wherein
a thickness of the second conductivity type emitter layer is equal to or less than 1 μm, and an impurity ion implantation step of forming the second conductivity type emitter layer is performed before impurity ion implantation steps of forming the second conductivity type base layer and the second conductivity type layer having the unfixed potential.

6. The high-voltage insulated gate type power semiconductor device according to claim 1, wherein
the thickness of the second conductivity type emitter layer formed on the back surface of the low-concentration first conductivity type base layer is between 1 μm and 10 nm.

7. The high-voltage insulated gate type power semiconductor device according to claim 1, wherein the gate electrode provided inside the trench is made of P type polysilicon.

8. A method of manufacturing a high-voltage insulated gate type power semiconductor device according to claim 6, comprising:
forming the first conductivity type buffer layer and the second conductivity type emitter layer on the back surface of the low-concentration first conductivity type base layer, and subsequently, forming the front surface structure including the trench and the MOS transistor structure on the front surface of the low-concentration first conductivity type base layer.

9. A high-voltage insulated gate type power semiconductor device comprising:
a low-concentration first conductivity type base layer;
a plurality of trenches selectively formed with large intervals and narrow intervals provided alternately, in a front surface of the low-concentration first conductivity type base layer;
a gate insulating film formed on a surface of each of the plurality of trenches;
a gate electrode formed inside the gate insulating film;
a second conductivity type base layer selectively formed between the adjacent trenches sharing the narrow interval;
a high-concentration first conductivity type source layer selectively formed on a front surface of the second conductivity type base layer;
a first main electrode connected to each of the second conductivity type base layer and the first conductivity type source layer;
a MOS transistor structure formed in surface portions of the first conductivity type source layer, the second conductivity type base layer, and the low-concentration first conductivity type base layer;
a second conductivity type layer formed between the adjacent trenches sharing the large interval so as not to be connected to the first main electrode, or connected to the first main electrode through a high resistor, the second conductivity type layer having the same degree of depth as the trench, and having an unfixed potential;
a first conductivity type buffer layer formed on a back surface of the low-concentration first conductivity type base layer so as to have a higher impurity concentration than the low-concentration first conductivity type base layer;
a high-concentration second conductivity type emitter layer formed on a front surface of the first conductivity type buffer layer; and
a second main electrode formed on a front surface of the second conductivity type emitter layer, wherein
a width S, trench depth D_{T}, gate insulating film thickness T_{OX}, and a gate drive voltage V_{ge} of a mesa region that is a structural portion including portion having the gate insulating film formed on the surface of the trenches and the MOS transistor structure have an inverse relationship with a scaling ratio k to reduce a size of a reference structure, and a cell width 2W is the same as a cell width in the reference structure, and when in the reference structure, an area ratio of an area which is in contact with the emitter electrode to an area which is not in contact with the emitter electrode or in contact through a high resistor, in an area sandwiched between centers of the trenches is 1:4 to 1:6, and the gate drive voltage V_{ge} of the high-voltage insulated gate type power semiconductor device having the reference structure in an on state is 15 V, the scaling ratio k is equal to or greater than 3.

10. The high-voltage insulated gate type power semiconductor device according to claim 9, wherein
the scaling ratio k is equal to or greater than 3, and a value provided by dividing an average value of impurity concentration gradients of the second conductivity type emitter layer by a total impurity amount of the second conductivity type emitter layer is smaller than values provided by dividing average values of the impurity concentration gradients of the second conductivity type layer having the unfixed potential and the second conductivity type base layer by total impurity amounts of the second conductivity type layer and the second conductivity type base layer, respectively.

11. The high-voltage insulated gate type power semiconductor device according to claim 9, wherein
the scaling ratio k is equal to or greater than 5.

12. The high-voltage insulated gate type power semiconductor device according to claim 9, wherein
a thickness of the second conductivity type emitter layer is equal to or less than 1 μm, and an impurity ion implantation step of forming the second conductivity type emitter layer is performed before impurity ion implantation steps of forming the second conductivity type base layer and the second conductivity type layer having the unfixed potential.

13. The high-voltage insulated gate type power semiconductor device according to claim 9, wherein
the thickness of the second conductivity type emitter layer formed on the back surface of the low-concentration first conductivity type base layer is between 1 μm and 10 nm.

14. A method of manufacturing a high-voltage insulated gate type power semiconductor device according to claim 13, comprising:
forming the first conductivity type buffer layer and the second conductivity type emitter layer on the back surface of the low-concentration first conductivity type base layer, and subsequently, forming the front surface structure including the trench and the MOS transistor structure on the front surface of the low-concentration first conductivity type base layer.

15. The high-voltage insulated gate type power semiconductor device according to claim 1, wherein the total cell width 2W is 15 μm to 20 μm, the scaling ratio k of the high-voltage insulated gate type power semiconductor device having the reference structure in an on state is equal to or greater than 3.

16. The high-voltage insulated gate type power semiconductor device according to claim 2 wherein a distance between centers of the adjacent trenches is 3 μm to 4 μm, the total cell width 2W is 15 μm to 20 μm, the scaling ratio k of the high-voltage insulated gate type power semiconductor device having the reference structure in an on state is equal to or greater than 3.

17. The high-voltage insulated gate type power semiconductor device according to claim 2, wherein
the scaling ratio k is equal to or greater than 3, and a value provided by dividing an average value of impurity concentration gradients of the second conductivity type emitter layer by a total impurity amount of the second conductivity type emitter layer is smaller than values provided by dividing average values of the impurity concentration gradients of the second conductivity type layer having the unfixed potential and the second conductivity type base layer by total impurity amounts of the second conductivity type layer and the second conductivity type base layer, respectively.

18. The high-voltage insulated gate type power semiconductor device according to claim 2, wherein
the scaling ratio k is equal to or greater than 5.

19. The high-voltage insulated gate type power semiconductor device according to claim 2, wherein
a thickness of the second conductivity type emitter layer is equal to or less than 1 μm, and an impurity ion implantation step of forming the second conductivity type emitter layer is performed before impurity ion implantation steps of forming the second conductivity type base layer and the second conductivity type layer having the unfixed potential.

20. The high-voltage insulated gate type power semiconductor device according to claim 3, wherein
the scaling ratio k is equal to or greater than 5.
